(19) United States
(12) Patent Application Publication
(10) Pub. No.: US 2006/0086520 A1
(43) Pub. Date: Apr. 27, 2006

(54) Electromagnetic interference shielding enclosure molded from fiber reinforced thermoplastic

(75) Inventor: Ronald P. Romano, Acton, MA (US)

Correspondence Address: FISH & NEAVE IP GROUP;ROPES & GRAY LLP, ONE INTERNATIONAL PLACE, BOSTON, MA, 02110-2624, US

(73) Assignee: PARKER HANNIFIN CORP., Cleveland, OH (US)

(21) Appl. No.: 11/246,430

(22) Filed: Oct. 7, 2005

Related U.S. Application Data
(60) Provisional application No. 60/617,449, filed on Oct. 8, 2004.

(51) Int. Cl. H05K 9/00

(52) U.S. Cl. 174/35 MS

(57) ABSTRACT

The invention discloses an EMI shielding enclosure having one or more EMI shielding vents as its integral part thereof. The enclosure as well as the vent is molded from a thermoplastic material filled with a conductive filler. Metal fibers, particles, flakes or metal-coated fibers are used as a filler to provide conductivity to otherwise dielectric thermoplastic matrix. Molding is done using available techniques such as injection molding and extrusion. In one particular configuration, the EMI vent is molded as a separate entity. Features such as bosses and grooves are provided on the vent to enable easy attachment with the shielding enclosure

### CROSS-REFERENCE TO RELATED APPLICATIONS

This application claims the benefit of priority from U.S. Provisional Application No. 60/617,449 filed on Oct. 8, 2004, the specification of which is incorporated herein by reference.

### BACKGROUND OF THE INVENTION

The present invention relates to electromagnetic interference (EMI) shielding enclosures and, more specifically, to EMI shielding vents molded as an integral section of EMI shielding enclosure using a thermoplastic material filled with electrically conductive filler.

The use of electronic devices such as televisions, computers, radios, cell phones and the like generate electromagnetic (EM) radiation emitted from their electronic circuitry. This radiation interferes with the proper functioning of other electronic devices in proximity to the source device. This phenomenon is known as Electromagnetic Interference (EMI). In order to confine EM radiation within the source device and to insulate that device from other neighboring devices, EMI shields are typically used.

Traditionally, EMI shielding of electronic circuits has been accomplished by using conductive metallic housing/enclosures. It works on the principle that a highly conductive material placed between a source of EM radiation (EM emitting device) and a receiver (neighbor device) attenuates the EM fields by reflection and absorption. The amount of attenuation depends on a number of factors such as the frequency of radiation, conductivity of the shield, permeability of the shield, and the distance from the source of radiation.

In addition to em radiation, most electronic devices dissipate heat while they are operating. Therefore, there is a need to provide a vent in the metallic housing to dissipate the heat. However, in the absence of any shield, these vents act as leakage points for EM radiation. Providing shielding to vents is therefore a crucial but challenging task. One common approach to shield these areas is to use ventilation panels, also known as vent panels. Traditional vent panels consist of a metallic honeycomb material assembled into a metallic frame. This assembly is then fastened to the enclosure with some type of EMI gasketing installed along the enclosure or vent panel surface.

Commercially available vent panels are generally made of aluminum. They allow airflow needed for cooling of electronic equipment inside the enclosure. At the same time, they do not allow EM radiation to escape from the enclosure. However, since aluminum is not very resilient, these vent panels are prone to damage.

A considerable amount of work has been done in this field with an aim to replace metal vents by more resilient and lighter substitutes.

U.S. Pat. No. 4,952,448 to Bullock et al discloses the use of fiber reinforced polymeric structure to make EMI shielding enclosures and vents.

U.S. Pat. No. 6,870,092 to Lambert et al discloses a vent panel that is made up of a dielectric panel and an electrically conducting layer is applied over it.

U.S. Pat. No. 4,596,670 to Liu discloses use of metal flakes and metal-coated fibers in thermoplastic matrix to make the matrix conducting. This conducting matrix can then be used as a raw material to make EMI shielding enclosures and vents. This and other aforementioned patents are incorporated herein in their entirety by way of reference thereto.

However, in all the aforementioned patents, EMI shielding vent panels are separately assembled to the shielding enclosure. Therefore there is a need for gasketry or additional attachment requirements. This results in additional effort and cost for the user.

Therefore, there is a perceived need to make EMI shielding vents an integral section of the shielding enclosure as opposed to a separately assembled piece, thus eliminating the need for additional attachment requirements.

Moreover, since commercially available vent panels are separately assembled, the panels are prominently visible on the enclosure and look out of place. Sometimes a major portion of the EMI shield is hidden inside the main casing of the device, and only the vent is visible along the outer surface. Since most of the devices are made from plastic or other polymers, the metal mesh of the vent does not look aesthetically pleasing to an observer.

Accordingly, an EMI shielding vent is needed which is a part of shielding enclosure and hence provides improved aesthetics to the shielding enclosure.

It as an objective of present invention to overcome the drawbacks of the prior art by providing vent panels that are an integral section of the shielding enclosure.

It is a further objective of the present invention to provide aesthetically appealing EMI shielding enclosures.

### SUMMARY OF THE INVENTION

To achieve the aforementioned objectives and to overcome the drawbacks of the prior art, the present invention discloses an EMI shielding enclosure with one or more vents molded as an integral part thereof. This is made possible with the help of conductive thermoplastic materials used to form the vent.

Since the vent is not a separately assembled piece, the present invention obviates any need for additional attachment requirements. This makes the EMI shield cost effective and good to look at. Moreover, the use of thermoplastic polymer provides additional advantage of resiliency and improved durability.

In a particular configuration of the present invention, the vent is molded as a separate entity and features such as bosses and grooves are incorporated into the design to ease its attachment to the main shield body.

In yet another embodiment, more than one vent is molded as a part of same enclosure. These vents may be of different shapes and/or dimensions.

### BRIEF DECRIPTION OF THE ACCOMPANYING DRAWINGS

FIG. 1 shows an EMI shielding enclosure for an electronic device.

FIG. 2A shows an EMI shield vent having hexagonal cells.

FIG. 2B shows an EMI shield vent having oval cells.

FIG. 2C shows an EMI shield vent having circular cells.

FIG. 2D shows an EMI shielding enclosure with two vents.

FIG. 3A shows a configuration of a molded vent that is used as a separate attachment on the shielding enclosure.

FIG. 3B shows view of the vent in FIG. 3A along the axis 3H-3H′.

### DETAILED DESCRIPTION OF THE INVENTION

The present invention discloses an EMI shielding vent, which is an integral section of an EMI shielding enclosure for an electronic device. The vent section of the unit and the enclosure are both molded from a thermoplastic material filled with an electrically conductive filler.

Thermoplastics are materials that soften when heated and harden when cooled. This property can be exploited to mold a softened thermoplastic into any desired shape. In addition to this, thermoplastics have high resilience and durability. However, thermoplastics are dielectric in nature. They can be made conducting by incorporating conducting flakes, particles or fibers in the thermoplastic matrix. These flakes/fibers/particles provide a conductive network in the dielectric matrix. Therefore, thermoplastics filled with electrically conductive fillers can be a suitable raw material for making EMI shields and vents.

The choice of the particular thermoplastic to use for a particular application depends on number of factors, such as the operating temperature, hardness, chemical compatibility, resiliency, flexibility etc. Depending upon the application, suitable materials may include polyesters, polycarbonates, polyester carbonates, polyamides, polyamide imides, polystyrenes, polyolefins, acrylonitrile butadiene styrene copolymers and blends thereof. These thermoplastic polymers may further comprise of one or more additional polymers and/or one or more rubber or rubber modified thermoplastic resins.

Suitable conductive fibers may be selected from the group consisting of silver, copper, nickel, aluminum or their alloys. Metal-coated fibers comprising graphite or glass fibers coated with nickel, silver, copper, aluminum or their alloys can also be used. Preferred conductive fibers are nickel coated graphite fibers since they make the resultant enclosure light in weight. Suitable fibers may essentially be of any length and diameter that is practical from both a composition and processing point of view.

The amount of conductive filler used in the practice of the invention depends on the level of EM shielding required. Typically, the amount will range from about 10 t0 30 percent by weight, with a higher level of conductive filler resulting in a greater degree of shielding.

Additionally, the fibers used in the present invention can be coated with any suitable coupling agents such as silane or titanate. They improve the compatibility of the fibers/flakes and the thermoplastic material. It is also possible to use more than one type of metal flake and/or fibers. One may further add glass, carbon or aramid fibers for providing strength and/or a desired amount of flame-retardants to the thermoplastic matrix.

The molding material may also be provided in the form of pellets comprising the fibers encased in a thermoplastic. The above-mentioned thermoplastic composition can be molded into the shape of a shielding enclosure with one or more vents using any of the standard available techniques such as extrusion and injection molding.

The present invention can be more clearly understood with the help of accompanying figures. It will be understood that the accompanying figures and their description is meant to be only for explanatory purposes, and is not otherwise meant to limit the application or its various embodiments.

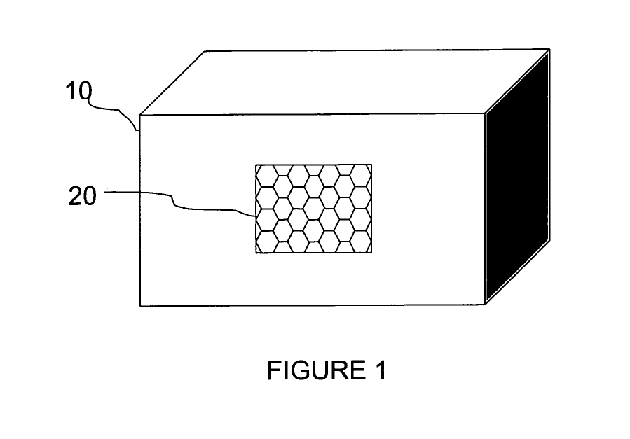

FIG. 1 shows an EMI shielding enclosure (10) of an electronic device (not shown) where a vent (20) has been provided to permit the flow of air. The shield as well as the vent has been molded from a thermoplastic filled with conductive filler. Use of a thermoplastic as a raw material allows molding of the shield in any shape depending upon the shape of the device. Molding can be done using any of the standard available methods such as extrusion and injection molding.

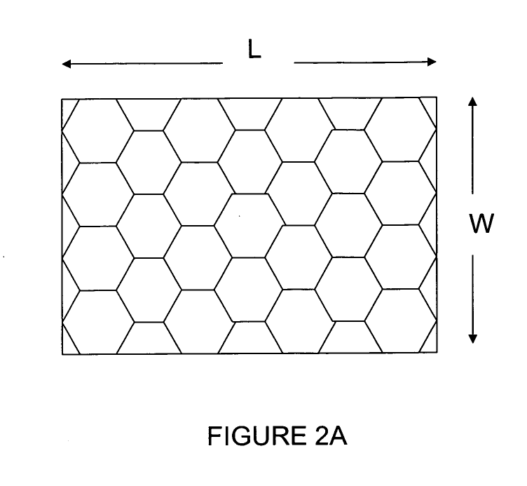

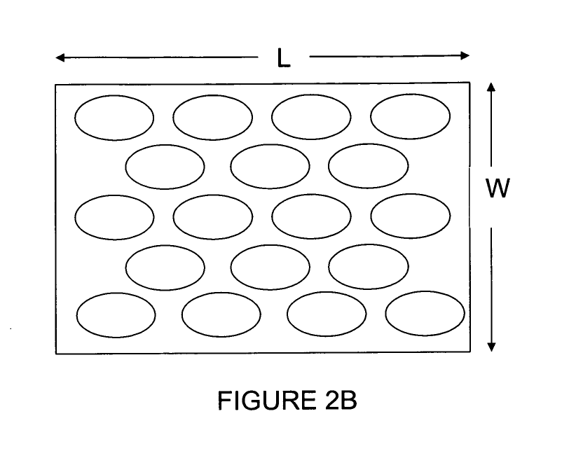

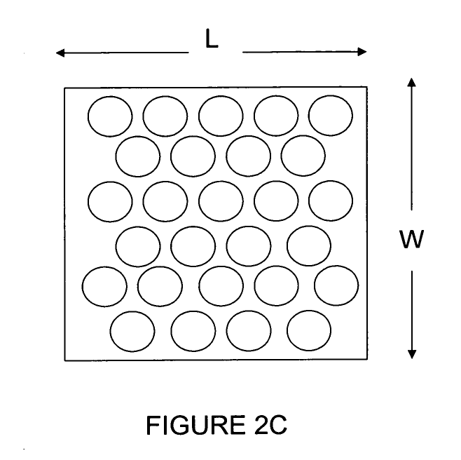

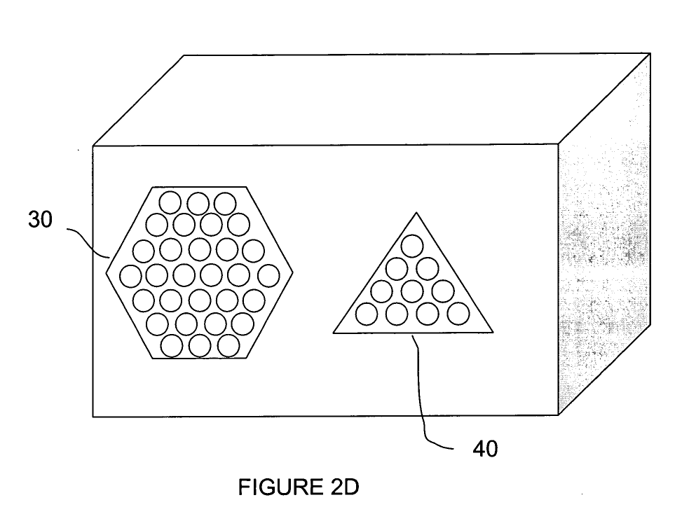

FIG. 2A shows a shielding vent (20) with honeycomb cells molded using a thermoplastic. The dimensions (length (L) and width (W)) of the vent depend on many factors such as the number of heat dissipating electronic components in the device, the frequency of operation of the device, and the effectiveness of the vent in permitting airflow. The dimensions of the cells are chosen according to the EMI shielding effectiveness required and the frequency of EM radiations to be shielded. Each cell essentially acts as a waveguide with a cut off frequency that is decided by the dimensions of the cell. These cells allow EM radiations with frequencies higher than the cut off but block lower frequency radiation.

As shown in FIG. 2B and FIG. 2C, the cells in the vent can be molded in oval or circular shapes. In addition, the cells can be molded into rectangular, square, or rhomboidal shapes, or any combinations thereof.

FIG. 2D shows some of the different possible shapes of the vent. The choice of shape depends on many factors such as the shape of the heat dissipating component of the device, the shape of the enclosure etc. More than one vent can be molded on the same EMI shielding enclosure. The figure shows a hexagonal (30) and a triangular vent (40) molded on a single shielding enclosure.

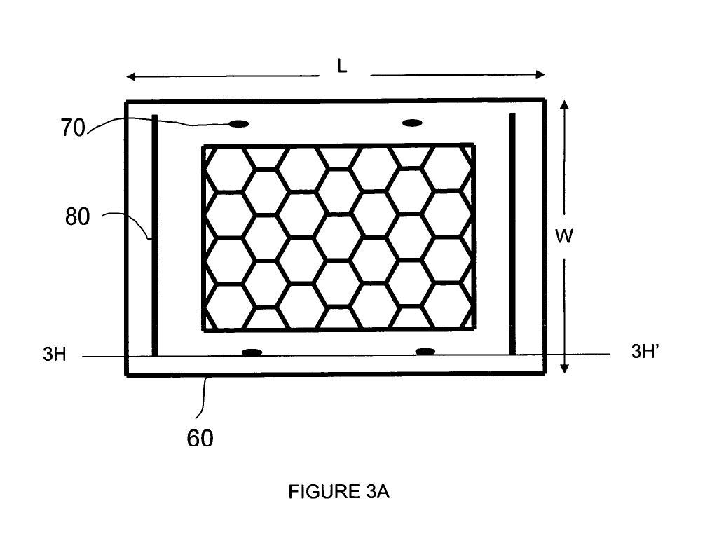

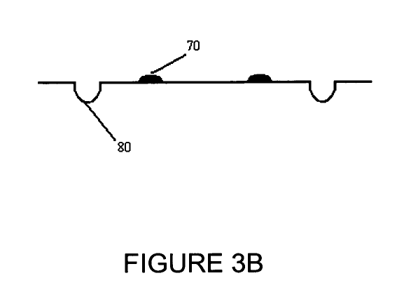

FIG. 3A shows an alternate configuration of the present invention. The shield vent (60) is molded as a separate entity. This vent is then attached to the shielding enclosure. Bosses (70) and grooves (80) have been incorporated into the design to ease attachment with the shielding enclosure. This eliminates the need for additional gasketry. This configuration is useful in devices where there is a need to remove the vent panel from the body of enclosure for purposes such as cleaning of the vent etc.

FIG. 3B shows a view of the configuration in FIG. 3A along axis 3H-3H′. Bosses (70) can be seen as knob-like swellings. Grooves (80) are narrow channels made on the vent panel. Both these features help in attaching the vent panel and the shielding enclosure.

The vents and the shield may be made in such a manner that the vents slide on and fit the shield for easy removal and attachment, without compromising functionality and aesthetics.

The invention has been defined with the aid of figures that show some of the configurations possible. However the invention is not limited by any of the embodiments shown. Various modifications and alterations are possible within the spirit of the invention, and the scope of the invention is only bound by the following claims.

What is claimed is:

1. An EMI shielding enclosure prepared from a thermoplastic material filled with a conductive filler wherein one or more EMI shielding vents are molded as an integral part of said enclosure.

2. The enclosure as claimed in claim 1, wherein said thermoplastic is selected from group consisting of polyesters, polycarbonates, polyester carbonates, polyamides, polyamide imides, polystyrenes, polyolefins, acrylonitrile butadiene styrene copolymers and blends thereof.

3. The enclosure as claimed in claim 1, wherein said conductive filler is made up of metal flakes selected from the group consisting of silver, copper, nickel, aluminum and their alloys.

4. The enclosure as claimed in claim 1, wherein said conductive filler is made up of metal fibers selected from the group consisting of silver, copper, nickel, aluminum and their alloys.

5. The enclosure as claimed in claim 1, wherein said conductive filler is made of metal-coated fibers.

6. The metal coated fibers as claimed in claim 5, wherein said fibers are made of glass or graphite.

7. The metal coated fibers as claimed in claim 5, wherein said coating includes copper, nickel, aluminum, silver or their alloys.

8. The enclosure as claimed in claim 1, wherein said conductive filler has more than one type of metal flakes and/or fibers.

9. The enclosure as claimed in claim 1, wherein reinforcing fibers including carbon and glass fibers are added to the thermoplastic matrix.

10. The enclosure as claimed in claim 1, wherein coupling agents are added to the thermoplastic matrix.

11. The enclosure as claimed in claim 1, wherein flame-retardants are added to the thermoplastic matrix.

12. The enclosure as claimed in claim 1, wherein the thermoplastic matrix contains rubber or rubber modified thermoplastic resin.

13. The enclosure as claimed in claim 1, wherein the amount of conductive filler is in the range of from about 10 to about 30 percent by weight.

14. The enclosure as claimed in claim 1, wherein said vent is molded in a shape selected from the group consisting of circular, oval, rectangular, square, triangular, rhomboidal and hexagonal shapes.

15. The enclosure as claimed in claim 1, wherein said vent has cells of a shape selected from the group consisting of circular, oval, rectangular, square, triangular, rhomboidal and hexagonal shapes.

16. An EMI shielding vent molded from thermoplastic material filled with a conductive filler wherein bosses and grooves are incorporated into said vent for easy attachment to an EMI shield enclosure.

17. The vent as claimed in claim 16, wherein said thermoplastic is selected from group consisting of polyesters, polycarbonates, polyester carbonates, polyamides, polyamide imides, polystyrenes, polyolefins, acrylonitrile butadiene styrene copolymers and blends thereof.

18. The vent as claimed in claim 16, wherein said conductive filler is made of metal flakes selected from the group consisting of silver, copper, nickel, aluminum and their alloys.

19. The vent as claimed in claim 16, wherein said conductive filler is made of metal fibers selected from the group consisting of silver, copper, nickel, aluminum and their alloys.

20. The vent as claimed in claim 16, wherein said conductive filler is made up of metal-coated fibers.

21. The metal coated fibers as claimed in claim 20, wherein said fibers are made of glass or graphite.

22. The metal coated fibers as claimed in claim 20, wherein said coating material includes copper, nickel, aluminum, silver or their alloys.

23. The vent as claimed in claim 16, wherein said conductive filler has more than one type of metal flakes and/or fibers.

24. The vent as claimed in claim 16, wherein reinforcing fibers including carbon and glass fibers are added to the thermoplastic matrix.

25. The vent as claimed in claim 16, wherein coupling agents are added to the thermoplastic matrix.

26. The vent as claimed in claim 16, wherein flame-retardants are added to the thermoplastic matrix.

27. The vent as claimed in claim 16, wherein the thermoplastic matrix contains rubber or a rubber modified thermoplastic resin.

28. The vent as claimed in claim 16, wherein the amount of conductive filler is in the range of from about 10 to about 30 percent by weight

29. The vent as claimed in claim 16, wherein said vent is molded in a shape selected from the group consisting of circular, oval, rectangular, square, triangular, rhomboidal and hexagonal shapes.

30. The vent as claimed in claim 16, wherein said vent has cells of a shape selected from the group consisting of rectangular, square, triangular, rhomboidal and hexagonal shapes.
